(19) United States
(12) Patent Application Publication
(10) Pub. No.: US 2025/0022840 A1
(43) Pub. Date: Jan. 16, 2025

(54) SEMICONDUCTOR POWER ENTITY AND METHOD FOR PRODUCING SUCH ENTITY BY HYBRID BONDING

(71) Applicant: Huawei Digital Power Technologies Co., Ltd., Shenzhen (CN)

(72) Inventors: Lasse Petteri PALM, Nuremberg (DE); Andreas Munding, Nuremberg (DE)

(73) Assignee: Huawei Digital Power Technologies Co., Ltd., Shenzhen (CN)

(21) Appl. No.: 18/890,986

(22) Filed: Sep. 20, 2024

Related U.S. Application Data
(63) Continuation of application No. PCT/EP2022/057489, filed on Mar. 22, 2023.

(51) Int. Cl. H01L 23/00; H01L 25/07; H05K 1/18; H05K 3/46

(52) U.S. Cl. CPC H01L 24/80; H05K 1/185; H05K 3/462; H01L 24/08; H01L 25/073; H01L 2224/08145; H01L 2224/8084; H01L 2224/80895; H01L 2224/80896; H01L 2224/80986; H01L 2924/13091; H05K 2201/10166; H05K 2203/1131

(57) ABSTRACT

A semiconductor power entity including a first laminate layer; a second laminate layer; an isolation layer arranged between the first laminate layer and the second laminate layer; a first metal layer arranged at a first laminate upper main face of the first laminate layer and a second metal layer arranged at a first laminate lower main face of the first laminate layer; a third metal layer arranged at a second laminate upper main face of the second laminate layer and a fourth metal layer arranged at a second laminate lower main face of the second laminate layer; and a connection metal layer embedded in the isolation layer between the first laminate layer and the second laminate layer, the connection metal layer forming an electrical connection with the second metal layer and the third metal layer.

### CROSS-REFERENCE TO RELATED APPLICATIONS

This application is a continuation of International Application No. PCT/EP2022/057489, filed on Mar. 22, 2022, the disclosure of which is hereby incorporated by reference in its entirety.

### TECHNICAL FIELD

The embodiments relate to the field of power products and production methods thereof, including relating to a semiconductor power entity and a method for producing such entity by hybrid bonding, a hybrid bonding method, and a corresponding structure.

### BACKGROUND

In order to increase power density and efficiency in next generation power packages, short, current-capable low-parasitic interconnection paths, a very good thermal management and electrical isolation are essential. Conductor traces with a current capability of several ten Amperes up to hundreds of Amperes, and power modules with an internal stray inductance below 10 nH are the current targets.

In today's chip embedding technology, only limited interconnect capabilities are available. For making connections between two vertically arranged power semiconductors on 2 different core layers, only micro-via interconnects are possible that are produced outside of both component's projected physical outline, i.e., outside of the die area. The through-via has to be placed in a minimum distance of about 400 to 500 μm from the embedded component edge in order to account for via process tolerances. This leads to a long routing distance and results in a high commutation loop inductance. Another severe disadvantage of this arrangement is the thermal decoupling by the usually low thermally conductive laminate layer between the two dies. Depending on the cooling situation on either side of the assembly, the dies could reach different operating temperature and develop a dispersive switching behavior.

### SUMMARY

The embodiments provide a solution for semiconductor power products and manufacturing such power products without the above-described disadvantages.

For example, the embodiments present a solution for a semiconductor power entity that has improved thermal characteristics and provides low parasitic interconnection paths.

The foregoing and other objects are achieved by the embodiments. Further implementation forms are apparent from the description and the figures.

A solution presented in the embodiments achieves these objects at a feasible cost by the combination of vertical system integration (3^{rd} dimension), panel level packaging, and low temperature metal joining (e. g. diffusion soldering or sintering). By the combination of these technologies, at least the following advantages can be realized:

Vertical system integration (3D-integration) drastically shortens interconnect length and allows to significantly increase the power density. According to the embodiments, this technology can be used in an industrialized scale for chip embedding or other panel level packaging technologies and for power device packaging.

Hybrid bonding according to the embodiments is a process that allows simultaneously bonding of metallic contacts & dielectric areas in one bonding process. Hybrid bonding can be used for 3D-integration on wafer level. A direct surface activated bonding (SAB) process can be used, which may require specialized high vacuum equipment and tight control of surface quality with a roughness in the range of about 1 nm, for example. This makes hybrid bonding in its current form unsuitable for power electronics packaging. The embodiments present a mechanism to make this technology available for panel level hybrid bonding process for power electronics packaging.

Chip embedding according to the embodiments employs PCB (printed circuit board) materials interfacing directly with the semiconductor die. In addition to excellent electrical and thermal performance, chip embedding (CE) offers at least the benefits of panel scale mass production. Currently, CE, which is still new technology, is not yet used for 3D stacking. It could be used, but due to limitations, e.g., direct vertical connections, it is not yet used (only one core layer, i.e., laminate layer).

According to the embodiments, vertical connections can be implemented between pre-manufactured PCB layers, resulting in a connection layer that embeds large connection metal areas in isolation material, achieving sufficient current carrying capability and thermal conductivity for power electronics.

The embodiments are based on the concept where direct vertical connections can be made between two or more laminate core layers, also referred to as laminate layers or core layers, where the vertical connections have the following characteristics: they can be made within the projected physical outline of embedded components; they are not confined to a certain shape (e. g. round) or size (e. g. 100 μm diameter); they do not need an outer layer plating process to form the electrical connection; they are suitable for power electronics (have low inductance and high current capability); they are reliable and do not remelt at bond temperature; they can be formed either by diffusion soldering or sintering.

A method or process to form these vertical connections has at least the following characteristics: using a standard PCB lamination process (bond temperature, pressure, format); using hybrid bonding to bond metal to metal and dielectric to dielectric in one step; several premanufactured layers can be connected to each other in one lamination step or in several sequential lamination steps; the bonding materials can be attached or applied to the surface of the laminate layers or placed between the laminate layers prior to bonding.

In case of diffusion soldering, the vertical metal-to-metal connection can be based on the formation of intermetallic phases in a selected bi- or multi metal system. The structure can have a minimum of three layers that contain at least one metal or metal alloy layer that has a low melting point and which is located between two separate metal layers that have a high melting point.

Some low melting point metals that can be used are, e.g., tin (Sn) and indium (In) and the high melting point metal or top metal layers are, e.g., copper (Cu), gold (Au), and silver (Ag). In diffusion soldering, the two high melting point metal layers can be bonded together by aim of at least one low temperature melting metal layer. During the bonding the layer can be pressed against each other and the temperature can be increased above the eutectic point for the selected metal system. Because the temperature is above the eutectic point of the selected metal system a liquid phase can appear and the metals can start to inter-diffuse and create intermetallic compounds (IMCs). Because the formed inter-metallics have a higher melting point, those are gradually solidified. If the bonding time is long enough all low melting point metals react with the high melting point metals to form inter-metallics and the joint is completely solidified. The formed intermetallic compounds have a significantly higher melting point than the low melting point metals and the joint does not melt anymore at the bonding temperature.

The diffusion soldering process can be divided into five phases that are wetting, alloying, liquid diffusion, gradual solidification and solid diffusion. The suitable metal, metal alloy or paste on one or both laminate layers or between the laminate layers (with metal) can be applied by plating, printing, dispensing or other suitable methods. Diffusion soldering or sintering can be used, for example, to form the metallic interconnection.

The described semiconductor power entity can be described by at least the following features, including: two or more laminate layers that i) are laminated together with isolating polymer layer; ii) have Cu metal routing at least on top and bottom side; iii) are electrically connected together with a non-re-meltable metal joint embedded in the isolating polymer layer.

Other features include: all laminate layers are PCB core layer in panel level (up to normal PCB production sizes); at least one laminate layer has power components embedded inside; the first power die in the first laminate layer and the second power die in the second laminate layer can face in different directions, but are not limited to this, in some other applications they can also face in the same direction. In one example, the first power die in the first laminate layer and the second power die in the second laminate layer can be arranged in a half bridge configuration. It may be understood that many other configurations of the two power dies can be implemented as well.

In order to describe the embodiments in detail, the following terms, abbreviations and notations will be used:
PCB printed circuit board
SAB surface activated bonding
HDI high density interconnect
SLID solid liquid interdiffusion
TLP transient liquid phase
TLPB transient liquid phase bonding
IMC intermetallic compound

The embodiments relate to a semiconductor power entity according to a first aspect, a method for producing such semiconductor power entity according to a second aspect, a computer program product according to a third aspect, and a non-transitory computer-readable medium according to a fourth aspect, as described in the following.

According to the first aspect, the embodiments relate to a semiconductor power entity, including: a first laminate layer having a first laminate upper main face and a first laminate lower main face opposing the first laminate upper main face; a second laminate layer having a second laminate upper main face and a second laminate lower main face opposing the second laminate upper main face; an isolation layer arranged between the first laminate layer and the second laminate layer; a first metal layer arranged at the first laminate upper main face of the first laminate layer and a second metal layer arranged at the first laminate lower main face of the first laminate layer; a third metal layer arranged at the second laminate upper main face of the second laminate layer and a fourth metal layer arranged at the second laminate lower main face of the second laminate layer; and a connection metal layer embedded in the isolation layer between the first laminate layer and the second laminate layer, the connection metal layer forming an electrical connection with the second metal layer and the third metal layer.

Such a semiconductor power entity provides at least the advantage of having direct vertical connections between two or more laminate core layers. These vertical connections can be made within the projected physical outline of embedded components if the laminate layer have such embedded components; they are not confined to a certain shape or size, i.e., they can be flexibly designed in shape and size; they do not need an outer layer plating process to form the electrical connection; they are suitable for power electronics, since they have low inductance and high current capability; they are reliable and do not remelt at bond temperature. These vertical connections can be formed, for example by solid-liquid interdiffusion (SLID), transient liquid phase (TLP) bonding or sintering.

Thus, the semiconductor power entity provides increased power density and efficiency, short, current-capable low-parasitic interconnection paths, a very good thermal management and improved electrical isolation. Conductor traces with a current capability of several ten Amperes up to hundreds of Amperes and even higher, and power modules with an internal stray inductance below about 10 nH and even lower can be achieved.

The first, second, third, and fourth metal layers can be redistribution or routing metal layers for redistributing or routing current paths. It can be understood that the semiconductor power entity is not restricted to these four metal layers and two laminate layers as examples shown in the Figures. The semiconductor power entity can also have more layers. The layers that are laminated may also be the layers of a multi-layer board, e.g., four layers or six layers, instead of the two-layer boards that are shown here in the Figures which are only examples for such a multi-layer board.

The semiconductor power entity can also be referred to as semiconductor power product. Such product can also be a module or a larger size product (PCB), for example, where the power components may be embedded inside the PCB and the rest of the components may be placed on top. Some or all of the passives may also be embedded in the PCB, depending on the passive components, e.g., depending on a type of the passive components.

In an exemplary implementation of the semiconductor power entity, the connection metal layer forms a non-remelting electrical and mechanical connection.

Such a “non-remelting” connection is different from a normal solder connection such as formed during a conventional TC/NCP process (thermo-compression bonding with solder and pre-applied non-conductive polymer). A non-remelting connection provides at least the advantage that it is a connection which will not remelt or decompose at temperatures much higher than the process temperature it was formed.

In an exemplary implementation of the semiconductor power entity, the connection metal layer forms one of a diffusion soldering connection or a sintering connection.

Diffusion soldering or diffusion bonding is a metal joining technique which can be advantageously applied to electronic packaging. It operates on the principle of interdiffusion of two dissimilar metals, where a liquid phase is completely transformed into solid state by metallic phase reactions and intermetallic compound formation. Similar terms for such technique are transient liquid phase bonding, solid-liquid interdiffusion, isothermal solidification. The technique provides at least the advantage that the resulting solid phase has a higher melting point than the temperature of the formation process.

Sintering is the process of compacting and forming a solid mass of material by heat or pressure without melting it to the point of liquefaction. Sintering happens as part of a manufacturing process used with metals, ceramics, plastics, and other materials. The atoms in the materials diffuse across the boundaries of the particles, fusing the particles together and creating one solid piece. An advantage of sintering is the following: because the sintering temperature does not have to reach the melting point of the material, sintering is often chosen as the shaping process for materials with extremely high melting points.

The connection metal can form a composed metal layer, for example. Such composed metal layer may include a compound from more than two metals, e.g., such as inter-metallic layer, or a connection of metal layers including one single metal, or a connection of a metal and a polymer or polymer mixture.

For such inter-metallic layer, the melting point of the inter metallic layer is higher than the lamination/process temperature where it was formed.

The connection metal layer may include more than 80% metal and less than 20% pores or polymers, for example.

The connection metal layer is designed for high current loads.

In one embodiment, the inter-metallic layer may have a minimum lateral size of >1 mm in each dimension, but not smaller than 0.1 mm.

The intermetallic layer may have a large cross-section, short length and good conductor and due to that is suitable for high current loads.

In one embodiment, the connection metal layer may have a thickness of 5 to 50 um, but not thicker than 0.2 mm (in case of a single layer structure).

In an exemplary implementation of the semiconductor power entity, the first laminate layer is embedding a first power semiconductor; and/or the second laminate layer is embedding a second power semiconductor.

Such a semiconductor power entity provides at least the advantage of increased power density and efficiency, short, current-capable low-parasitic interconnection paths, a very good thermal management and improved electrical isolation. Conductor traces with a high current capability of, e.g., several ten amperes up to hundreds of amperes, and power modules with an internal stray inductance, e.g., below about 10 nH can be implemented.

When defining a first power semiconductor and a second power semiconductor this does not exclude that more than one first power semiconductor can be embedded in the first laminate layer and more than one second power semiconductor can be embedded in the second laminate layer.

In an exemplary implementation of the semiconductor power entity, the connection metal layer vertically connects the second metal layer with the third metal layer providing a vertical electrical connection for the first power semiconductor and the second power semiconductor.

This provides at least the advantage that a shortest-path electrically connection can be realized which reduces stray inductance of the power entity and impedance between the two metal layers.

In an exemplary implementation of the semiconductor power entity, the connection metal layer forms a direct electrical connection path between the first power semiconductor and the second power semiconductor without a detour via through-hole vias arranged laterally to the two power semiconductors.

As described above, such a direct electrical connection path provides at least the advantage of shortest-path large area electrical connection between the two metal layers, reducing impedance and stray inductance.

In an exemplary implementation of the semiconductor power entity, the second metal layer and/or the third metal layer includes at least one of copper, gold, silver, palladium or nickel or a combination thereof; where in case of a diffusion soldering connection, the connection metal layer includes any suitable low temperature melting metal like for example tin and indium in combination with any of the metals of the second metal layer or the third metal layer or an alloy thereof; where in case of a sintering connection, the connection metal layer includes a porous layer of silver or copper or other suitable sintering metal with optional polymer filling.

This provides at least the advantage that a lot of metals and metal alloys or combinations thereof with different characteristics can be applied

Note that such connection metal layer includes also the following combination: (tin OR indium OR (tin AND indium)) in combination with any of the metals of the second metal layer or the third metal layer or an alloy thereof.

In an exemplary implementation of the semiconductor power entity, the first power semiconductor and the second power semiconductor are configured to form a half bridge configuration. It can be understood that a lot of other configurations of the two power semiconductors can be implemented as well.

This provides at least the advantage that the semiconductor power entity can be efficiently used in automotive power conversion systems and in other applications of the semiconductor power entity. The half bridge configuration is a reoccurring key topology element in power electronics conversion circuits.

In an exemplary implementation of the semiconductor power entity, the first power semiconductor is a vertical device including at least one first terminal opposing the first laminate upper main face and a second terminal opposing the first laminate lower main face; and the second power semiconductor is a vertical device including at least one first terminal opposing the second laminate upper main face and a second terminal opposing the second laminate lower main face.

This provides at least the advantage that the semiconductor power entity can provide high current density, high power dissipation and high reverse breakdown voltage.

In an alternative exemplary implementation of the semiconductor power entity, the first power semiconductor can be a lateral device and the second power semiconductor can be a lateral device.

In an exemplary implementation of the semiconductor power entity, as described below with respect to FIG. 2a, the semiconductor power entity includes: at least one first via and at least one second via extending through the first laminate layer, the at least one first via forming an electrical connection between the at least one first terminal of the first power semiconductor and the first metal layer and the at least one second via forming an electrical connection between the second terminal of the first power semiconductor and the second metal layer; and at least one third via and at least one fourth via extending through the second laminate layer, the at least one third via forming an electrical connection between the at least one first terminal of the second power semiconductor and the third metal layer and the at least one fourth via forming an electrical connection between the second terminal of the second power semiconductor and the fourth metal layer.

Such a design provides at least the advantage that the shortest path between the two facing inner terminals of the power semiconductors can be used for electrical connection. This results in low parasitic impedance, high current capability of this buried connection due to large area. It can be even made larger than the die itself. Without the described technique, such connections are only possible by arrangement of through-holes at the periphery outside the projected die area.

By such design both power semiconductors can be fully embedded in the respective laminate layers which results in excellent electrical performance.

In an alternative embodiment, as shown below with respect to FIGS. 2c to 2e, these vias can be replaced by large area connections such that either the die front or the die back side can be in direct connection to the metal layers without any distance. Note that the large area connections can be made on one face of the chip per layer. With development and process modification large area connections can be on both sides, but in such a case there most likely would be one large area connection/via instead of multiple small vias.

These large area connections have at least the advantage that configurations are possible that allow further optimization of a) parasitic impedance by shortening the electrical path, or b) thermal path by enabling direct heat extraction without microvias at the outer surface of the entity.

In an exemplary implementation of the semiconductor power entity, as described below with respect to FIGS. 4a to 4d and FIG. 5, the first power semiconductor has a first semiconductor upper main face and a first semiconductor lower main face opposing the first semiconductor upper main face; where the first semiconductor upper main face is coplanar arranged with the first laminate upper main face to form an electrical connection between the at least one first terminal of the first power semiconductor and the first metal layer at the first laminate upper main face; and where the second terminal of the first power semiconductor forms an electrical connection with the second metal layer at the first laminate lower main face by one or more microvias extending through the first laminate layer. Alternatively, the first semiconductor lower main face is coplanar arranged with the first laminate lower main face to form an electrical connection between the second terminal of the first power semiconductor and the second metal layer at the first laminate lower main face; and where the at least one first terminal of the first power semiconductor forms an electrical connection with the first metal layer at the first laminate upper main face by one or more microvias extending through the first laminate layer.

Such a design provides at least the advantage of large area chip connection on one side of the chip with the respective metal layer which provides improved thermal dissipation and improved electrical performance.

In an exemplary implementation of the semiconductor power entity, the second power semiconductor has a second semiconductor upper main face and a second semiconductor lower main face opposing the second semiconductor upper main face; where the second semiconductor upper main face is coplanar arranged with the second laminate upper main face to form an electrical connection between the at least one first terminal of the second power semiconductor and the third metal layer at the second laminate upper main face; and where the second terminal of the second power semiconductor forms an electrical connection with the fourth metal layer at the second laminate lower main face by one or more microvias extending through the second laminate layer. Alternatively, the second semiconductor lower main face is coplanar arranged with the second laminate lower main face to form an electrical connection between the second terminal of the second power semiconductor and the fourth metal layer at the second laminate lower main face; and where the at least one first terminal of the second power semiconductor forms an electrical connection with the third metal layer at the second laminate upper main face by one or more microvias extending through the second laminate layer

Such a design provides at least the same advantage of large area chip connection on one side of the chip with the respective metal layer as described above. This large area chip connection results in improved thermal dissipation and improved electrical performance.

According to the second aspect, the embodiments relate to a method for producing a semiconductor power entity, as described below with respect to FIGS. 4a to 4d and FIG. 5, the method including: providing a first laminate layer embedding a first power semiconductor, the first laminate layer having a first laminate upper main face and a first laminate lower main face opposing the first laminate upper main face; where a first metal layer is arranged at the first laminate upper main face of the first laminate layer and a second metal layer is arranged at the first laminate lower main face of the first laminate layer; providing a second laminate layer embedding a second power semiconductor, the second laminate layer having a second laminate upper main face and a second laminate lower main face opposing the second laminate upper main face; where a third metal layer is arranged at the second laminate upper main face of the second laminate layer and a fourth metal layer is arranged at the second laminate lower main face of the second laminate layer; applying a bonding metal at the second metal layer of the first laminate layer and/or the third metal layer of the second laminate layer, the bonding metal being placed between the first power semiconductor and the second power semiconductor and/or between respective electrical contact pairs in the first laminate layer and the second laminate layer, arranging an isolation layer between the second metal layer of the first laminate layer and the third metal layer of the second laminate layer; and laying-up and laminating the first laminate layer, the second laminate layer and the isolation layer to a semiconductor power entity, where the laminating transforms the bonding metal to a connection metal layer forming an electrical connection with the second metal layer and the third metal layer.

Such method or process provides at least the advantage to form the above-described vertical connections. The method or process provides at least the following advantageous characteristics: use of a standard PCB lamination process with respect to bond temperature, pressure, format; use of hybrid bonding to bond metal to metal and dielectric to dielectric in one step; several premanufactured layers can be connected to each other in one lamination step or in several sequential lamination steps; the bonding materials can be attached or applied to the surface of the laminate layers or placed between the laminate layers prior to bonding.

In an exemplary implementation of the method, the connection metal layer is formed simultaneously with the lamination of the first laminate layer, the second laminate layer and the isolation layer.

This provides at least the advantage that the fabrication method can be simplified due to performing two production steps simultaneously.

In an exemplary implementation of the method, as described below with respect to FIG. 4a, the method includes: applying the bonding metal at the second metal layer of the first laminate layer before the laying-up and laminating; and applying the isolation layer at the third metal layer of the second laminate layer before the laying-up and laminating, where the isolation layer is structured to form an opening for embedding the bonding metal.

This provides at least the advantage of flexibility in the sequence of the different production steps. It does not matter, for example, to which laminate layer the bonding metal or the isolation layer is applied to. They only need to be complementary.

In an exemplary implementation of the method, applying the bonding metal includes plating of metals, printing or dispending of pastes, placing of preforms; and where applying the isolation layer includes printing, coating, laminating or dispensing of dielectric material.

This provides at least the advantage of providing alternatives for application of the bonding metal and application of the isolation layer.

In an exemplary implementation of the method, as described below with respect to FIG. 4d, the method includes: applying the isolation layer at the third metal layer of the second laminate layer before the laying-up and laminating, where the isolation layer is structured to form an opening for embedding the bonding metal; and placing the bonding metal into the opening of the isolation layer on the third metal layer.

This provides at least the advantage of flexibility in the sequence of the different production steps.

In an exemplary implementation of the method, as described below with respect to FIG. 4b, the method includes: placing the isolation layer between the second metal layer of the first laminate layer and the third metal layer of the second laminate layer during the laying-up and laminating, where the isolation layer is non-structured.

This provides at least the advantage of flexibility in the sequence of the different production steps.

In an exemplary implementation of the method, as described below with respect to FIG. 4c, the method includes: placing the isolation layer between the second metal layer of the first laminate layer and the third metal layer of the second laminate layer during the laying-up and laminating, where the isolation layer is structured to form an opening for embedding the bonding metal.

This provides at least the advantage of providing alternatives for placement of the isolation layer.

Following process steps of the above method may be optional: drilling holes in the semiconductor power entity extending from the first metal layer to the fourth metal layer, where the holes are drilled laterally to the first and second power semiconductors; metal plating the holes to form metal plated through holes electrically connecting the first and optionally second, third metal layers with the fourth metal layer; and structuring the first metal layer and the fourth metal layer.

According to the third aspect, the embodiments relate to a computer program product including computer executable code or computer executable instructions that, when executed, causes at least one computer to execute the method according to the second aspect described above.

The computer program product may run on a controller or a processor for implementing the above method to produce the semiconductor power entity according to the first aspect described above.

According to a fourth aspect, the embodiments relate to a non-transitory computer-readable medium, storing instructions that, when executed by a computer, cause the computer to execute the method according to the second aspect described above. Such a computer readable medium may be a non-transient readable storage medium. The instructions stored on the non-transitory computer-readable medium may be executed by a controller or a processor.

### BRIEF DESCRIPTION OF THE DRAWINGS

Further embodiments will be described with respect to the following figures, in which:

FIG. 1a shows a schematic diagram illustrating production of a semiconductor power product without using hybrid bonding according to the embodiments;

FIG. 1b shows a schematic diagram illustrating production of a semiconductor power product using hybrid bonding according to the embodiments;

FIG. 2a shows a schematic cross section of a semiconductor power entity according to a first embodiment;

FIG. 2b shows a schematic cross section of a semiconductor power entity according to a second embodiment;

FIG. 2c shows a schematic cross section of a semiconductor power entity according to a third embodiment;

FIG. 2d shows a schematic cross section of a semiconductor power entity according to a fourth embodiment;

FIG. 2e shows a schematic cross section of a semiconductor power entity according to a fifth embodiment;

FIG. 3 shows different options for producing the metal stack for panel level hybrid bonding according to the embodiments, where

FIG. 3a shows one-layer, single sided as a first option,

FIG. 3b shows one-layer, double sided as a second option,

FIG. 3c shows multi-layer, single or double sided as a third option, and

FIG. 3d shows pre-form as a fourth option;

FIG. 4a shows a process flow diagram of a method for producing a semiconductor power entity according to a first embodiment referring to resin printing;

FIG. 4b shows a process flow diagram of a method for producing a semiconductor power entity according to a second embodiment referring to non-structured resin sheet;

FIG. 4c shows a process flow diagram of a method for producing a semiconductor power entity according to a third embodiment referring to structured prepreg or resin sheet;

FIG. 4d shows a process flow diagram of a method for producing a semiconductor power entity according to a fourth embodiment referring to preform placement;

FIG. 5 shows a schematic diagram illustrating a method for producing a semiconductor power entity according to the embodiments.

### DETAILED DESCRIPTION OF EMBODIMENTS

In the following detailed description, reference is made to the accompanying drawings, which form a part thereof, and in which is shown by way of illustration specific aspects in which the embodiments may be practiced. It is understood that other aspects may be utilized and structural or logical changes may be made without departing from their scope. The following detailed description, therefore, is not to be taken in a limiting sense.

It is understood that comments made in connection with a described method may also hold true for a corresponding device or system configured to perform the method and vice versa. For example, if a specific method step is described, a corresponding device may include a unit to perform the described method step, even if such unit is not explicitly described or illustrated in the figures. Further, it is understood that the features of the various exemplary aspects described herein may be combined with each other, unless specifically noted otherwise.

In the embodiments, diffusion soldering is described. The principle of diffusion soldering is applied to microelectronics since the 1960ies. It is also known as solid liquid interdiffusion (SLID), transient liquid phase bonding (TLPB), or isothermal solidification. It was since then applied to 3D-integration/chip-stacking and MEMS wafer level encapsulation. Diffusion soldering is an irreversible process, the connection does not remelt at the same temperature it is formed, but at a much higher temperature because all low-temperature melting solder is transformed into intermetallic compounds which have a higher melting temperature.

In the embodiments, sintering is described. Sintering is another low temperature metal joining technology that allows to make non-remeltable stable and reliable connections at a relatively low bond temperature. It is based on the high self-diffusion and surface diffusion property of some metals (silver and copper are most known and applied today), for example if the initially surface is very large. In some situations, a paste is printed and dried on a noble metal surface. The paste contains silver particles of different sizes and with a specific coating that prevents premature agglomeration and unwanted sintering. Under temperature and pressure, the dried paste densifies into a porous metal layer that forms a metallurgical bond with the compatible metal surfaces in contact. Another way to offer large sinterable metal surfaces is in form of metal filaments or wires that are grown on the contact surface, with diameters in the lower m down to upper nm range and lengths of several tens of m.

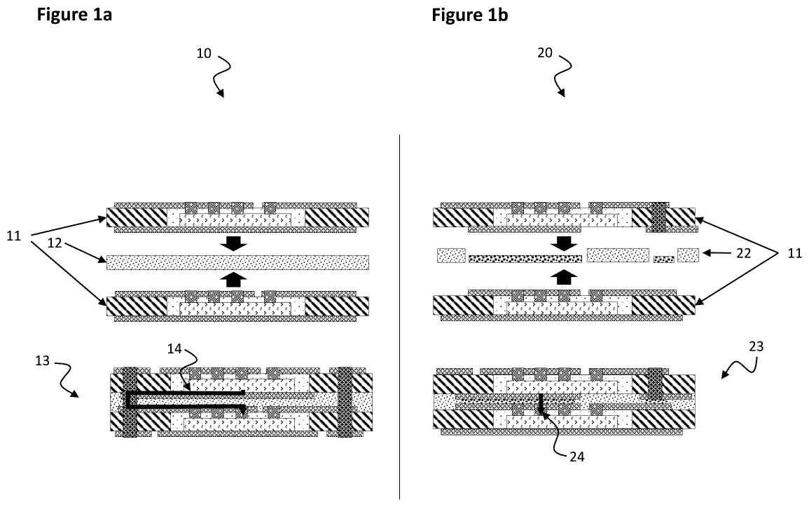

FIG. 1a shows a schematic diagram illustrating production 10 of a semiconductor power product 13 without using hybrid bonding according to the embodiments; while FIG. 1b shows a schematic diagram illustrating production 20 of a semiconductor power product 23 using hybrid bonding according to the embodiments.

In FIG. 1a, two laminate embedded power die panels 11 are provided and a prepreg sheet 12 in between. After lamination a semiconductor power product 13 with a stacked die half-bridge is produced. No direct vertical connections between the stacked dies are possible.

The semiconductor power product 13 is characterized by an indirect electrical path 14 with high parasitics (R, L) and an interrupted thermal path.

In FIG. 1b, the two laminate embedded power die panels 11 are provided and hybrid bond materials 22 in between. After lamination a semiconductor power product 23 with a stacked die half-bridge is produced. The hybrid bonding method enables direct vertical connections 24 for large currents.

In contrast to the semiconductor power product 13 of FIG. 1a, semiconductor power product 23 shown in FIG. 1b is characterized by direct electrical path 24, low parasitics (R, L) and continuous thermal path.

This embodiments present a method how two or more laminate layers, (with or without embedded dies), e.g., two or more of the laminate embedded power die panels 11 shown in FIG. 1b, can be vertically connected with respect to each other. This method combines chip embedding and PCB lamination with low temperature metal joining technology. The low temperature metal joining technology can be either based on diffusion soldering (e. g., SLID (solid liquid interdiffusion), TLPB (transient liquid phase) bonding) or sintering (e.g., Ag sintering, Cu sintering, nano filament assisted sintering).

One basic idea of the embodiments is that during one single process step the metal areas can be electrically and thermally connected using SLID bonding, diffusion bonding, sintering or nano wires and the other areas can be bonded, laminated or glued together with nonconductive polymer material. The bonding process can be performed at a relatively low temperature. The metals and polymer bonding materials can be selected in such a way that the bonding can be realized in approximately the same or lower temperature than the curing of the polymer bonding material. The method allows to irreversibly connect two layers with embedded components vertically together with a non-remeltable connection that allows excellent electrical and thermal performance and high reliability.

The hybrid bonding method according to the embodiments includes the following steps: providing the laminate with redistribution layer (RDL); applying bond materials to the bond surfaces of the laminates or panels to be connected, e.g., metallization for SLID, TLPS, polymer/glue; the lay-up step; the lamination/bonding step; and the singulation step. It understands that additional PCB processes can be done between these steps.

Several possible options for the application of the materials to the bond surface, the structure of the bond materials, and the interaction of the bond materials with the bond surface are described below.

This embodiments provide an essential building block for power packaging on panel level, for example for laminate based large scale packaging. It enables more degrees of freedom in design of current capable in-package electrical and thermal connections in the vertical dimension. The vertical connections can have different areas and shapes by design. They can be used to effectively shorten critical conductor lengths or strengthen the thermal path.

Using hybrid bonding as shown in FIG. 1b provides at least the following benefits: a) simultaneous metal/metal and polymer/polymer bonding leads to fewer process steps, no underfill process necessary; b) high reliable and non-meltable low parasitics electrical interconnection between laminate layers; c) 3D integrated of power devices; vertical stacked packaging with up to 2× increase of power density; d) panel level packaging of vertically stacked devices; processing and tooling cost down; e) make direct vertical connections inside the package and reduce package parasitics; note that this kind of embedded connections between layers that are laminated together are not possible with conventional PCB processes; f) make thermal connections to a heatsink using a panel level lamination process.

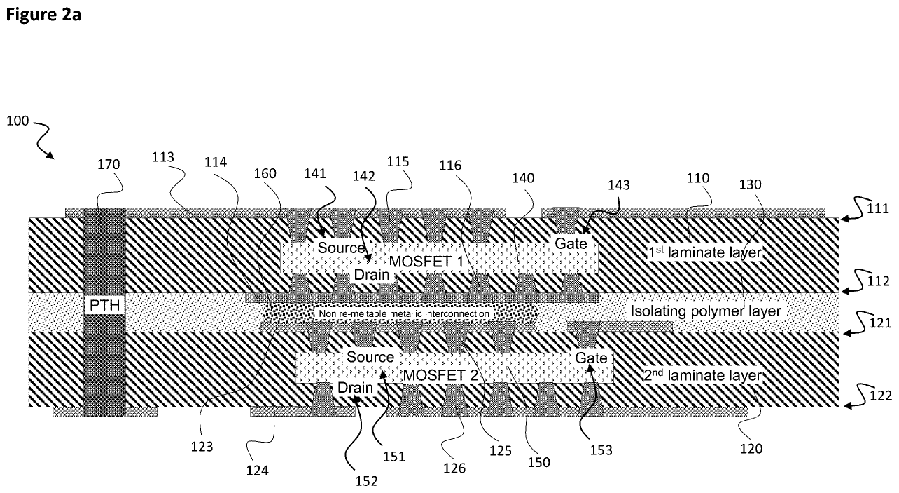

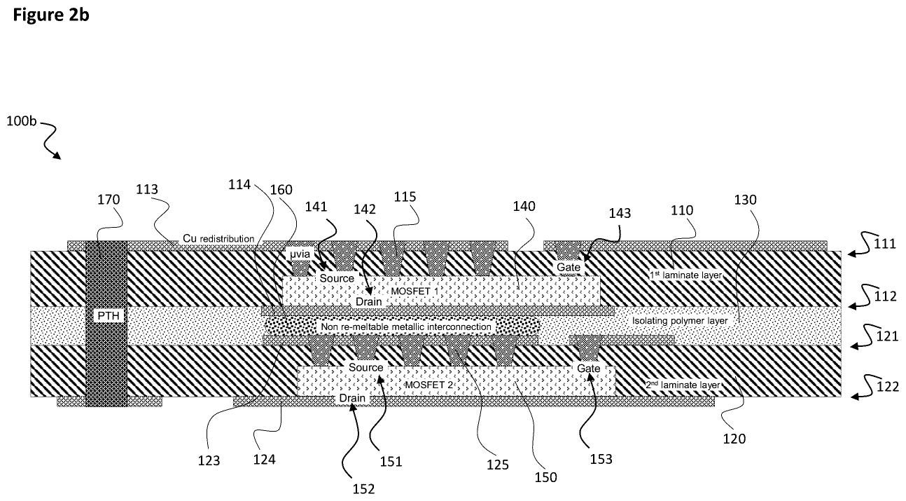

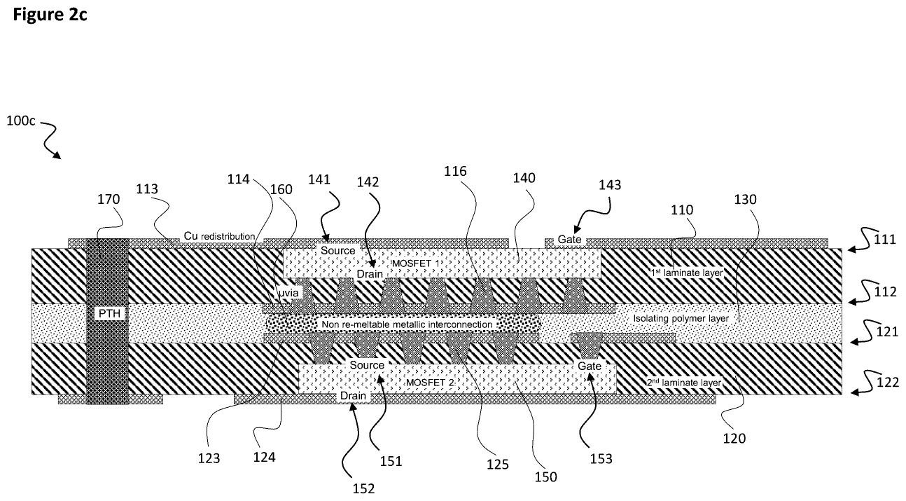

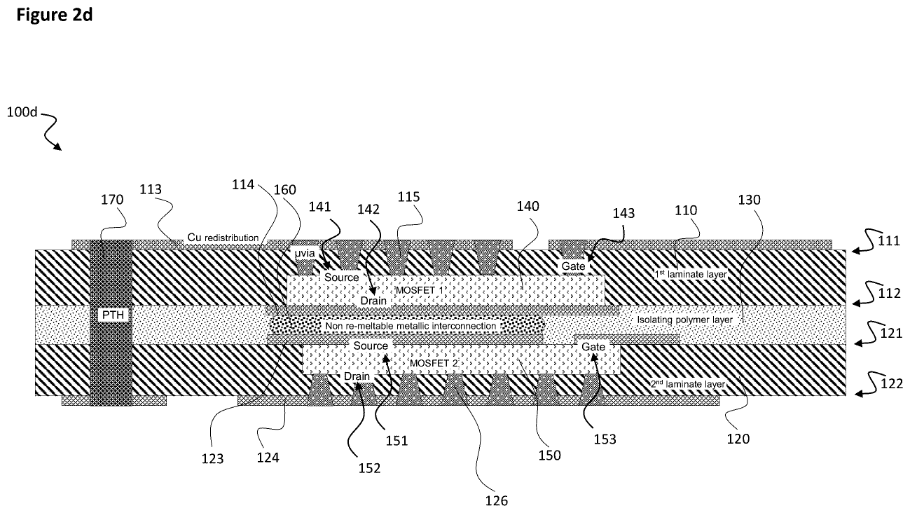

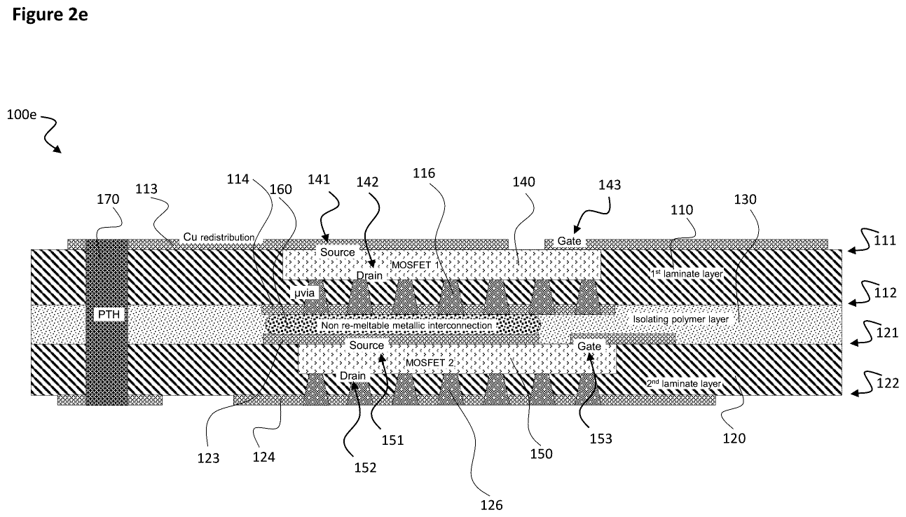

FIG. 2a shows a schematic cross section of a semiconductor power entity 100 according to a first embodiment.

The semiconductor power entity 100, also referred to as a semiconductor power product, includes a first laminate layer 110 having a first laminate upper main face 111 and a first laminate lower main face 112 opposing the first laminate upper main face 111; and a second laminate layer 120 having a second laminate upper main face 121 and a second laminate lower main face 122 opposing the second laminate upper main face 121.

The semiconductor power entity 100 includes an isolation layer 130 arranged between the first laminate layer 110 and the second laminate layer 120.

The semiconductor power entity 100 includes a first metal layer 113 arranged at the first laminate upper main face 111 of the first laminate layer 110 and a second metal layer 114 arranged at the first laminate lower main face 112 of the first laminate layer 110.

The semiconductor power entity 100 includes a third metal layer 123 arranged at the second laminate upper main face 121 of the second laminate layer 120 and a fourth metal layer 124 arranged at the second laminate lower main face 122 of the second laminate layer 120.

The semiconductor power entity 100 includes a connection metal layer 160 embedded in the isolation layer 130 between the first laminate layer 110 and the second laminate layer 120. The connection metal layer 160 is forming an electrical connection with the second metal layer 114 and the third metal layer 123.

The first, second, third and fourth metal layers 113, 114, 123, 124 can be redistribution or routing metal layers for redistributing or routing current paths.

As mentioned above, the semiconductor power entity can also be referred to as semiconductor power product. Such product can also be a module or a larger size product (PCB), for example, where the power components are embedded inside the PCB and the rest of the components on top. As described above, also part of the passives can be embedded inside the PCB.

The connection metal layer 160 can form a non-remelting electrical and mechanical connection.

Such a “non-remelting” connection is different from a normal solder connection such as formed during a conventional TC/NCP process (thermo-compression bonding with solder and pre-applied non-conductive polymer). A non-remelting connection is a connection which does not remelt in same temperatures at which the connection was formed.

The connection metal layer 160 can form one of a diffusion soldering connection or a sintering connection as described above.

The connection metal 160 can form a composed metal layer, for example. Such composed metal layer may include a compound from more than two metals, e.g., such as inter-metallic layer, or a connection of metal layers including one single metal, or a connection of a metal and a polymer or polymer mixture.

For such inter-metallic layer, the melting point of the inter metallic layer is higher than the lamination/process temperature where it was formed.

The connection metal layer may include more than 80% metal and less than 20% pores or polymers, for example.

The connection metal layer is designed for high current loads.

In one embodiment, the inter-metallic layer may have a minimum lateral size of greater than 1 mm in each dimension, but not smaller than about 0.1 mm.

The intermetallic layer may have a large cross-section, short length and good conductor and due to that is suitable for high current loads.

In one embodiment, the inter-metallic layer may have a thickness of about 5 to 50 μm, but not thicker than about 0.2 mm (in case of a single layer structure).

As mentioned above, the laminate layers may embed or not embed power dies.

The first laminate layer 110 may embed a first power semiconductor 140 as shown in FIG. 2a and/or the second laminate layer 120 may embed a second power semiconductor 150 as shown in FIG. 2a. In one example, only one of the laminate layers 110, 120 may be embedding a semiconductor component.

When defining a first power semiconductor and a second power semiconductor this does not exclude that more than one first power semiconductor can be embedded in the first laminate layer 110 and more than one second power semiconductor can be embedded in the second laminate layer 120.

The connection metal layer 160 may vertically connect the second metal layer 114 with the third metal layer 123 providing a vertical electrical connection for the first power semiconductor 140 and the second power semiconductor 150.

The connection metal layer 160 may form a direct electrical connection path between the first power semiconductor 140 and the second power semiconductor 150 without a detour via through-hole vias arranged laterally to the two power semiconductors 140, 150, e.g., as exemplarily illustrated by the direct connection path 24 in FIG. 1b.

The second metal layer 114 and/or the third metal layer 123 may include at least one of copper, gold, silver, palladium or nickel or a combination thereof. In case of a diffusion soldering connection, the connection metal layer 160 may include any of a suitable low temperature melting metal like for example the metals tin and indium in combination with any of the metals of the second metal layer 114 or the third metal layer 123 or an alloy thereof. In case of a sintering connection, the connection metal layer 160 may include a porous layer of silver or copper or other suitable sintering metal with optional polymer filling.

Note that such connection metal layer can include also the following combination: (tin OR indium OR (tin AND indium)) in combination with any of the metals of the second metal layer (114) or the third metal layer (123) or an alloy thereof.

The first power semiconductor 140 and the second power semiconductor 150 may be configured to form a half bridge configuration.

The first power semiconductor 140 can be a vertical device including at least one first terminal 141, 143 (e.g., source 141 and gate 143 as shown in FIG. 2a) opposing the first laminate upper main face 111 and a second terminal 142 (e.g., drain 142 as shown in FIG. 2a) opposing the first laminate lower main face 112.

The second power semiconductor 150 can be a vertical device including at least one first terminal 151, 153 (e.g., source 151 and gate 153 as shown in FIG. 2a) opposing the second laminate upper main face 121 and a second terminal 152 (e.g. drain 152 as shown in FIG. 2a) opposing the second laminate lower main face 122.

The semiconductor power entity 100 may include at least one first via 115 and at least one second via 116 extending through the first laminate layer 110. The at least one first via 115 may form an electrical connection between the at least one first terminal 141, 143 of the first power semiconductor 140 and the first metal layer 113. The at least one second via 116 may form an electrical connection between the second terminal 142 of the first power semiconductor 140 and the second metal layer 114.

The semiconductor power entity 100 may include at least one third via 125 and at least one fourth via 126 extending through the second laminate layer 120. The at least one third via 115 may form an electrical connection between the at least one first terminal 151, 153 of the second power semiconductor 150 and the third metal layer 123. The at least one fourth via 126 may form an electrical connection between the second terminal 152 of the second power semiconductor 150 and the fourth metal layer 124.

In an alternative embodiment as described below with respect to FIGS. 2b to 2e, the vias 115, 116 can be replaced by large area connections such that the die front or back side can be in direct connection to the metal layers 113, 123 without any distance. Note that the large area connections can be made on one face of the chip per layer as exemplified in FIGS. 2b to 2e. With development and process modification large area connection can be on both sides (but in such a case there most likely would be one large area connection/via instead of multiple small vias).

FIG. 2b shows a schematic cross section of a semiconductor power entity 100b according to a second embodiment. In this second embodiment, a direct electrical and thermal path of lower power semiconductor to outer surface of power entity can be implemented. This corresponds to the scenario where a high side switch of a half-bridge configuration has direct electrical and thermal path to outer surface of power entity.

This second embodiment is similar to the first embodiment, but the first power semiconductor 140 is directly connected to the second metal layer 114 without applying vias. Similarly, the second power semiconductor 150 is directly connected to the fourth metal layer 124 without applying vias in between.

In this second embodiment, the first power semiconductor 140 has a first semiconductor upper main face and a first semiconductor lower main face opposing the first semiconductor upper main face. The second power semiconductor 150 has a second semiconductor upper main face and a second semiconductor lower main face opposing the second semiconductor upper main face.

The first semiconductor lower main face is coplanar arranged with the first laminate lower main face 112 to form an electrical connection between the second terminal 142 of the first power semiconductor 140 and the second metal layer 114 at the first laminate lower main face 112. The at least one first terminal 141, 143 (e.g., source and gate) of the first power semiconductor 140 forms an electrical connection with the first metal layer 113 at the first laminate upper main face 111 by one or more microvias 115 extending through the first laminate layer 110.

Similarly, the second semiconductor lower main face is coplanar arranged with the fourth laminate lower main face 122 to form an electrical connection between the second terminal 152 (e.g., drain) of the second power semiconductor 150 and the fourth metal layer 124 at the second laminate lower main face 122. The at least one first terminal 151, 153 (e.g., source and gate) of the second power semiconductor 150 forms an electrical connection with the third metal layer 123 at the second laminate upper main face 121 by one or more microvias 125 extending through the second laminate layer 120.

FIG. 2c shows a schematic cross section of a semiconductor power entity 100c according to a third embodiment.

This third embodiment is similar to the first embodiment, but the first power semiconductor 140 is directly placed below and connected to the first metal layer 113 without applying vias in between. Similarly, the second power semiconductor 150 is directly placed on and connected to the fourth metal layer 124 without applying vias in between. In this third embodiment, a direct electrical and thermal path is implemented to outer surface of the power entity. This third embodiment is beneficial at least for heat extraction to external heatsink because the main thermal path has no microvias. It is further beneficial at least for lowest stray inductance for half-bridge configurations, where MOSFET 1 (140) is the low side switch and MOSFET 2 (150) is the high-side switch.

In this third embodiment, the first power semiconductor 140 has a first semiconductor upper main face and a first semiconductor lower main face opposing the first semiconductor upper main face. The second power semiconductor 150 has a second semiconductor upper main face and a second semiconductor lower main face opposing the second semiconductor upper main face.

The first semiconductor upper main face is coplanar arranged with the first laminate upper main face 111 to form an electrical connection between the at least one first terminal 141, 143 (e.g., source and gate) of the first power semiconductor 140 and the first metal layer 113 at the first laminate upper main face 111. The second terminal 142 (e.g., drain) of the first power semiconductor 140 forms an electrical connection with the second metal layer 114 at the first laminate lower main face 112 by one or more microvias 116 extending through the first laminate layer 110.

Similarly, the second semiconductor lower main face is coplanar arranged with the fourth laminate lower main face 122 to form an electrical connection between the second terminal 152 (e.g., drain) of the second power semiconductor 150 and the fourth metal layer 124 at the second laminate lower main face 122. The at least one first terminal 151, 153 (e.g., source and gate) of the second power semiconductor 150 forms an electrical connection with the third metal layer 123 at the second laminate upper main face 121 by one or more microvias 125 extending through the second laminate layer 120.

FIG. 2d shows a schematic cross section of a semiconductor power entity 100d according to a fourth embodiment. In this fourth embodiment, the shortest possible direct chip-to-chip connection can be implemented. This fourth embodiment is at least beneficial for lowest chip-to-chip connection impedance.

This fourth embodiment is similar to the first embodiment, but the first power semiconductor 140 is directly placed on the second metal layer 114 without applying vias. Similarly, the second power semiconductor 150 is directly placed below the third metal layer 123 without applying vias.

In this fourth embodiment, the first power semiconductor 140 has a first semiconductor upper main face and a first semiconductor lower main face opposing the first semiconductor upper main face. The second power semiconductor 150 has a second semiconductor upper main face and a second semiconductor lower main face opposing the second semiconductor upper main face.

The first semiconductor lower main face is coplanar arranged with the first laminate lower main face 112 to form an electrical connection between the second terminal 142 of the first power semiconductor 140 and the second metal layer 114 at the first laminate lower main face 112. The at least one first terminal 141, 143 (e.g., source and gate) of the first power semiconductor 140 forms an electrical connection with the first metal layer 113 at the first laminate upper main face 111 by one or more microvias 115 extending through the first laminate layer 110.

Similarly, the second semiconductor upper main face is coplanar arranged with the second laminate upper main face 121 to form an electrical connection between the at least one first terminal 151, 153 (e.g., source and gate) of the second power semiconductor 150 and the third metal layer 123 at the second laminate upper main face 121. The at second terminal 152 (e.g., drain) of the second power semiconductor 150 forms an electrical connection with the fourth metal layer 124 at the second laminate lower main face 122 by one or more microvias 125 extending through the second laminate layer 120.

FIG. 2e shows a schematic cross section of a semiconductor power entity 100e according to a fifth embodiment. In this fifth embodiment, a direct electrical and thermal path of upper power semiconductor 140 to outer surface of power entity can be implemented. This fifth embodiment can be used for the implementation of a low side switch of a half-bridge configuration which has direct electrical and thermal path to outer surface of power entity.

This fifth embodiment is similar to the first embodiment, but the first power semiconductor 140 is directly placed below the first metal layer 113 without applying vias. Similarly, the second power semiconductor 150 is directly placed below the third metal layer 123 without applying vias.

In this fifth embodiment, the first power semiconductor 140 has a first semiconductor upper main face and a first semiconductor lower main face opposing the first semiconductor upper main face. The second power semiconductor 150 has a second semiconductor upper main face and a second semiconductor lower main face opposing the second semiconductor upper main face.

The first semiconductor upper main face is coplanar arranged with the first laminate upper main face 111 to form an electrical connection between the at least one first terminal 141, 143 (e.g., source and gate) of the first power semiconductor 140 and the first metal layer 113 at the first laminate upper main face 111. The second terminal 142 (e.g., drain) of the first power semiconductor 140 forms an electrical connection with the second metal layer 114 at the first laminate lower main face 112 by one or more microvias 116 extending through the first laminate layer 110.

Similarly, the second semiconductor upper main face is coplanar arranged with the second laminate upper main face 121 to form an electrical connection between the at least one first terminal 151, 153 (e.g., source and gate) of the second power semiconductor 150 and the third metal layer 123 at the second laminate upper main face 121. The second terminal 152 (e.g., drain) of the second power semiconductor 150 forms an electrical connection with the fourth metal layer 124 at the second laminate lower main face 122 by one or more microvias 125 extending through the second laminate layer 120.

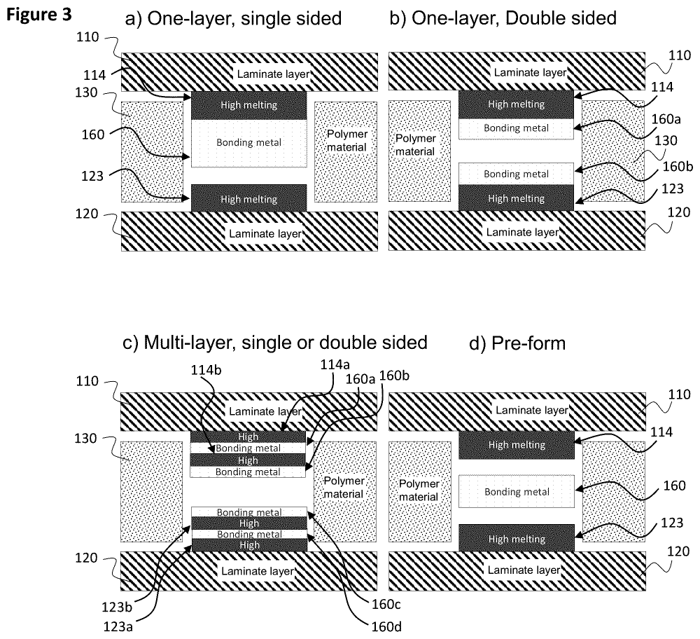

FIG. 3 shows different options for producing the metal stack for panel level hybrid bonding according to the embodiments. FIG. 3a shows one-layer, single sided as a first option. FIG. 3b shows one-layer, double sided as a second option. FIG. 3c shows multi-layer, single or double sided as a third option. FIG. 3d shows pre-form as a fourth option. Although the picture was originally intended for slid bonding, it can also be applied to sintering and hybrid bonding according to the embodiments.

In all FIGS. 3a to 3d a semiconductor power entity is illustrated including a first laminate layer 110, also referred to as a first substrate, having a first laminate upper main face 111 and a first laminate lower main face 112 opposing the first laminate upper main face 111, e.g., as illustrated in FIGS. 2a to 2e; a second laminate layer 120 having a second laminate upper main face 121 and a second laminate lower main face 122 opposing the second laminate upper main face 121, e.g., as illustrated in FIGS. 2a to 2e.

The semiconductor power entity includes an isolation layer 130, e.g., made of polymer material, arranged between the first laminate layer 110 and the second laminate layer 120, where the isolation layer 130 can be either arranged in between the laminate layers 110, 120 during stack-up or be attached/applied to either but not both of the laminate layers 110, 120 facing main faces before stack-up.

The semiconductor power entity may include a first metal layer 113 arranged at the first laminate upper main face 111 of the first laminate layer 110 (not shown in FIGS. 3a to 3d) and a fourth metal layer 124 arranged at the second laminate lower main face 122 of the second laminate layer 120 (not shown in FIGS. 3a to 3d).

The semiconductor power entity of FIG. 3a includes a second metal layer 114 arranged at the first laminate lower main face 112 of the first laminate layer 110 and a third metal layer 123 arranged at the second laminate upper main face 121 of the second laminate layer 120. As shown in FIG. 3a, these can be single metal layers 114, 123 made of high melting material.

The semiconductor power entity of FIG. 3a includes a connection metal layer 160 embedded in the isolation layer 130 between the first laminate layer 110 and the second laminate layer 120, the connection metal layer 160 forming an electrical connection with the second metal layer 114 and the third metal layer 123 after lamination. The connection metal layer 160 can be a single layer made of bonding metal attached to the second metal layer 114 of high melting material as illustrated in FIG. 3a.

The semiconductor power entity of FIG. 3b is similar to FIG. 3a, however, the connection metal layer 160 is made of two parts 160a and 160b of bonding metal which are attached to the respective second metal layer 114 and third metal layer 123 made of high melting material.

The semiconductor power entity of FIG. 3c is similar to FIG. 3a, however, the second metal layer 114, the third metal layer 123 and the connection metal layer 160 are implemented as a first multi-layer which is formed of respective portions 114a, 114b of the second metal layer arranged alternately with respective portions 160a, 160b of the connection metal layer; and a second multi-layer which is formed of respective portions 123a, 123b of the third metal layer arranged alternately with respective portions 160c, 160d of the connection metal layer.

The semiconductor power entity of FIG. 3d is similar to FIG. 3a, however, the connection metal layer 160 is made of a pre-form of bonding metal applied between the second metal layer 114 and the third metal layer 123 made of high melting material.

In the semiconductor power entities shown in FIGS. 3a to 3d, the different metal stack options for panel level hybrid bonding are illustrated. The bonding metal can also be applied as paste for sintering or diffusion soldering. The polymer material can be a sheet material, printed, dispensed or pre-laminated or any other suitable form.

The embodiments shown in FIGS. 3a to 3d can be implemented by the different bond material combinations, metal stack options and process options as illustrated in Table 1. Some important combinations are described as embodiments, i.e., the embodiments shown in FIGS. 3a, 3b, 3c and 3d, where low melting material is denoted as bonding metal.

| | | Contact metals/High meltingpoint metals | | | | |
|---|---|---|---|---|---|---|
| Bond metals | | Cu | Ni | Au | Pd | Ag |
| Low melting | Sn | Diff. sold. | Diff. sold. | Diff. sold. | Diff. sold. | Diff. sold. |
| point metals | In | Diff. sold. | Diff. sold. | Diff. sold. | Diff. sold. | Diff. sold. |
| | Sn:In | Diff. sold. | Diff. sold. | Diff. sold. | Diff. sold. | Diff. sold. |
| | Sn:Ag | Diff. sold. | Diff. sold. | Diff. sold. | Diff. sold. | Diff. sold. |
| Sinter material | Ag paste | Sinter | — | Sinter | Sinter | Sinter |
| | Cu paste | Sinter | — | Sinter | Sinter | Sinter |
| | Ag filaments | Sinter | Sinter | Sinter | Sinter | Sinter |
| | Cu filaments | Sinter | Sinter | Sinter | Sinter | Sinter |

Table 1: Example of possible metal systems for low temperature joining. Columns: High temperature melting metals; Rows: Low temperature melting metals and sinter materials. The cell content denotes the type of non-remelting metal joint that can be formed by that combination: Either “Diff. sold.”=diffusion soldering (SLID, TLPB) or “Sinter”=sintering.

Table 1 is non-exhaustive. It lists some practical and available metal combinations. It can be understood that this table 1 is just an example not limiting the embodiments to these combinations. All other suitable low temperature diffusion solder metal combinations and all other low temperature sinter metals and particle shapes may be applied as well.

The following metals and bonding layer options may exist inter alia (see Table 1):

1) The high temperature melting metal can be one layer structure (e.g. Cu. Ni) or multilayer structure (e.g. Cu+Au, Cu+Ni, Ni+Au, Cu+Ni+Au).

2) The low temperature melting metal can be Sn, In or some other suitable metal, metal alloy or combination of several metals e.g., SnAg, InSn.

3) The bonding layer can be liquid or film type polymer material e.g. epoxy, epoxy mixture, BT epoxy, PI or other type of polymer that is compatible with laminate materials

4) The bonding material can be uncured, precured or semicured.

The following metal stack options are illustrated in FIGS. 3a to 3d:

a) The low melting and high melting metals on laminate can be a simple one-layer structure or printed paste on only one laminate layer (high melting metal+low temperate metal/metal alloy stack), see FIG. 3a.

b) The low melting and high melting metals on laminate can be a simple one layer structure or printed paste on both laminate layers (high melting metal+low temperate metal/metal alloy stack), see FIG. 3b.

c) The low melting and high melting metals on laminate can be a multilayer sandwich or other type of structure on one or both laminate layers (high+low+high+low . . . ), see FIG. 3c.

d) The low melting temperate metal or metal alloy or metal paste can be in a separate preform that is placed between the laminates, see FIG. 3d.

The following process/step options can be applied:

1) The low temperature metal or metal alloy or metal paste layer and/or polymer bonding layer is on one or two sides of the laminate.

2) The low temperature metal or metal alloy or metal compound layer is on one or two side of the laminate and the polymer bonding layer is brought between in separate step.

3) The polymer bonding layer is on one or two side of the laminate and the low temperature metal or metal alloy or metal paste preform is brought between in separate step.

4) The polymer bonding layer and the low temperature metal or metal alloy or metal paste preform are brought between in the laminate during layup process.

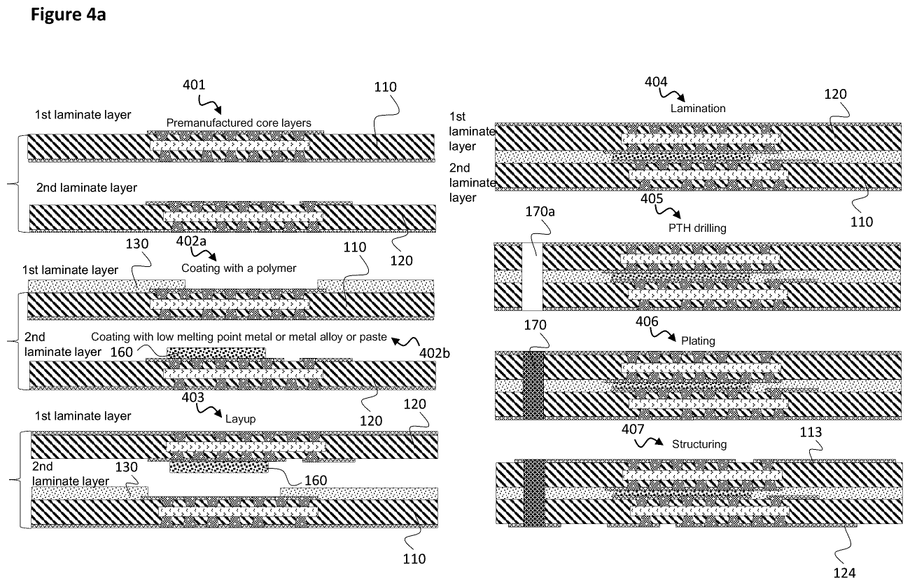

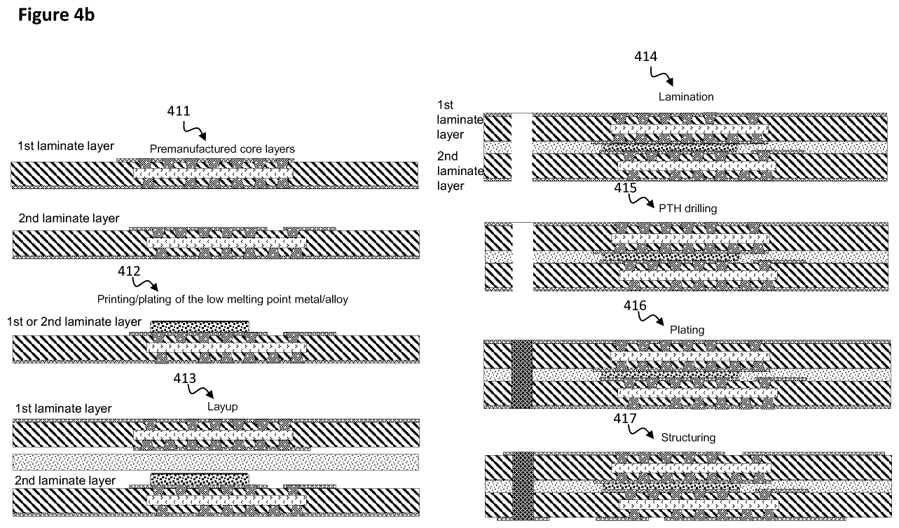

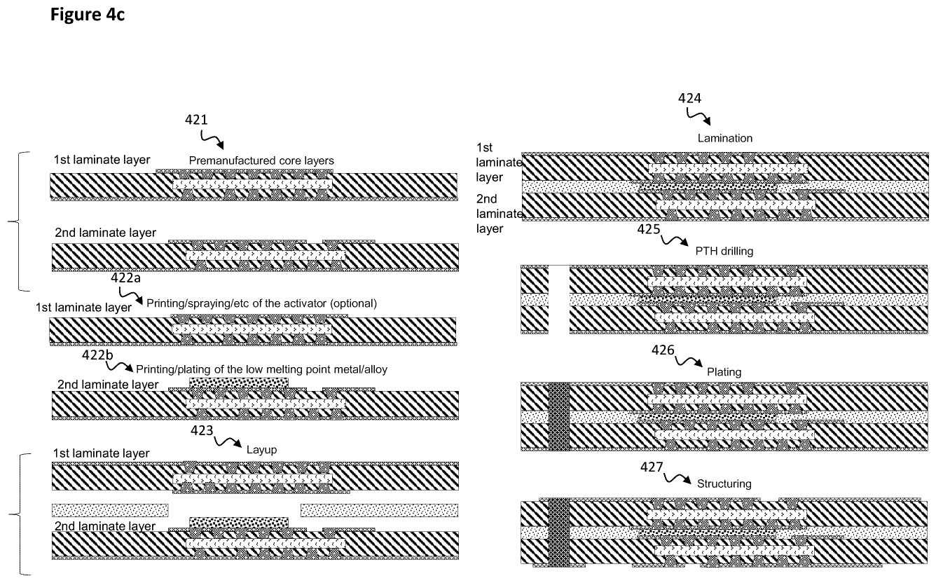

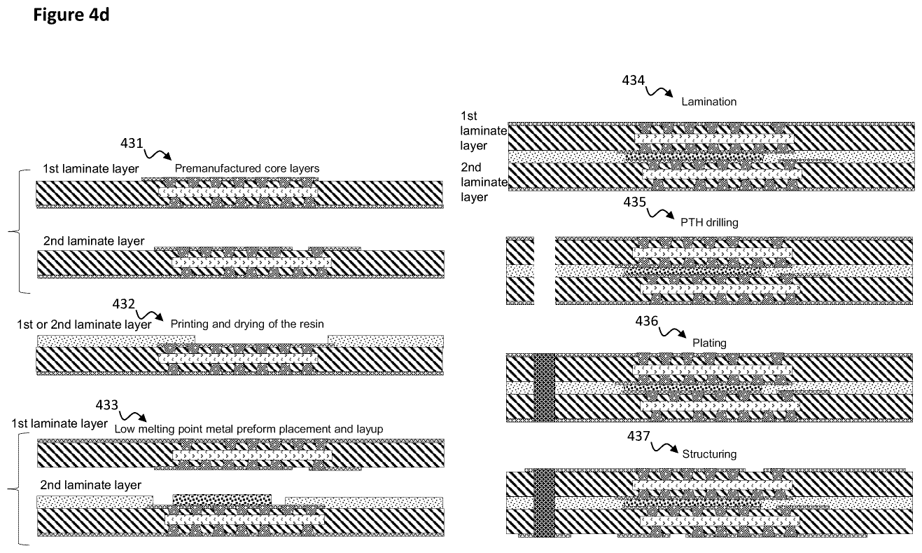

The different process flow options are described below with respect to FIGS. 4a, 4b, 4c and 4d. In addition to the described process flows, also combination of modifications from the descried options can be used.

FIG. 4a shows a process flow diagram of a method for producing a semiconductor power entity according to a first embodiment referring to resin printing.

This process option 1—Resin printing—describes a process where the polymer bonding material is printed, coated, laminated; dispensed, etc., on one (or two) laminate layers and the bonding metal is plated, printed, dispensed on one (or two) laminate layers before the bonding.

In a first step, two premanufactured laminate layers, also referred to as core layers or laminate core layers, are provided 401 which are printed with the polymer bonding material. The two premanufactured laminate layers may correspond to the first laminate layer 110 and the second laminate layer 120 described above with respect to FIGS. 2a to 2e.

In a second step, the first premanufactured laminate layer 110 is coated 402a with the polymer bonding material and the second premanufactured laminate layer 120 is coated 402b with low melting point metal or metal alloy or paste.

In a third step, the second premanufactured laminate layer 120 is turned around and arranged above the first premanufactured laminate layer 110 to provide a layup 403

In a fourth step, the layup 403 is laminated 404 to provide a semiconductor power product.

In a fifth step, one or more holes are drilled 405 in the semiconductor power product.

In a sixth step, the one or more holes are plated 406 by a conductive metal layer

In a seventh step, the semiconductor power product is structured 407, e.g., by structuring the first metal layer 113 and the fourth metal layer 124.

If no holes 170 are used at this phase, the metal layer can also be structured in an earlier phase and this seventh step is not needed. This applies as well to all other process options 2 to 4 described below.

Depending on the design and application the above-described fifth, sixth and seventh steps are optional and can be applied as well to all other process options 2 to 4 described below.

FIG. 4b shows a process flow diagram of a method for producing a semiconductor power entity according to a second embodiment referring to non-structured resin sheet.

This process option 2—Non-structured resin sheet—describes a process where the bonding metal is plated, printed, dispensed on one (or two) laminate layers before the bonding and the non-structured polymer material is placed between the laminate layers during layup and lamination process.

In a first step, two premanufactured laminate layers 411 are provided that may correspond to the first laminate layer 110 and second laminate layer 120 described above with respect to FIGS. 2a to 2e.

In a second step one of the premanufactured laminate layers is printed or plated 412 with low melting point metal or metal alloy.

In a third step, a layup 413 is provided of the first and second premanufactured laminate layers and a polymer layer in between.

In a fourth step, the layup 403 is laminated 414 to provide a semiconductor power product.

In a fifth step, one or more holes are drilled 415 in the semiconductor power product.

In a sixth step, the one or more holes are plated 416 by a conductive metal layer

In a seventh step, the semiconductor power product is structured 417, e.g. by structuring the first metal layer 113 and the fourth metal layer 124.

If no holes 170 are used at this phase, the metal layer can also be structured in an earlier phase and this seventh step is not needed. Depending on the design and application the above-described fifth, sixth and seventh steps are optional.

FIG. 4c shows a process flow diagram of a method for producing a semiconductor power entity according to a third embodiment referring to structured prepreg or resin sheet.

This process option 3—Structured prepreg or resin sheet—describes a process where the bonding metal is plated, printed, dispensed on one (or two) laminate layers before the bonding and the structured polymer material is placed between the laminate layers during layup and lamination process.

In a first step, two premanufactured laminate layers 421 are provided that may correspond to the first laminate layer 110 and second laminate layer 120 described above with respect to FIGS. 2a to 2e.

In a second step, activator material is printed, sprayed, etc. 422a on the first premanufactured laminate layer and the premanufactured second laminate layer is printed or plated 422b with low melting point metal or metal alloy.

In a third step 423, a layup 423 is provided of the first and second premanufactured laminate layers and a structured polymer layer in between.

In a fourth step, the layup 423 is laminated 424 to provide a semiconductor power product.

In a fifth step, one or more holes are drilled 425 in the semiconductor power product.

In a sixth step, the one or more holes are plated 426 by a conductive metal layer

In a seventh step, the semiconductor power product is structured 427, e.g., by structuring the first metal layer 113 and the fourth metal layer 124.

If no holes 170 are used at this phase, the metal layer can also be structured in an earlier phase and this seventh step is not needed. Depending on the design and application the above-described fifth, sixth and seventh steps are optional.

FIG. 4d shows a process flow diagram of a method for producing a semiconductor power entity according to a fourth embodiment referring to preform placement.

This process option 4—Preform placement—describes a process where the polymer bonding material is printed, coated, laminated, dispensed, etc., on one (or two) laminate layers and the bonding metal preform is placed (e.g. pick and placement process) on copper pad on lover laminate layers before the bonding before the bonding.

In a first step, two premanufactured laminate layers 431 are provided that may correspond to the first laminate layer 110 and second laminate layer 120 described above with respect to FIGS. 2a to 2e.

In a second step, one of the two premanufactured laminate layers 431 is printed with resin and the resign is dried 432

In a third step, a low melting point metal preform is placed on the resign printed premanufactured laminate layer and a layup 433 is provided together with the other premanufactured laminate layer.

In a fourth step, the layup 423 is laminated 434 to provide a semiconductor power product.

In a fifth step, one or more holes are drilled 435 in the semiconductor power product.

In a sixth step, the one or more holes are plated 436 by a conductive metal layer

In a seventh step, the semiconductor power product is structured 437, e.g., by structuring the first metal layer 113 and the fourth metal layer 124.

If no holes 170 are used at this phase, the metal layer can also be structured in an earlier phase and this seventh step is not needed. Depending on the design and application the above-described fifth, sixth and seventh steps are optional.

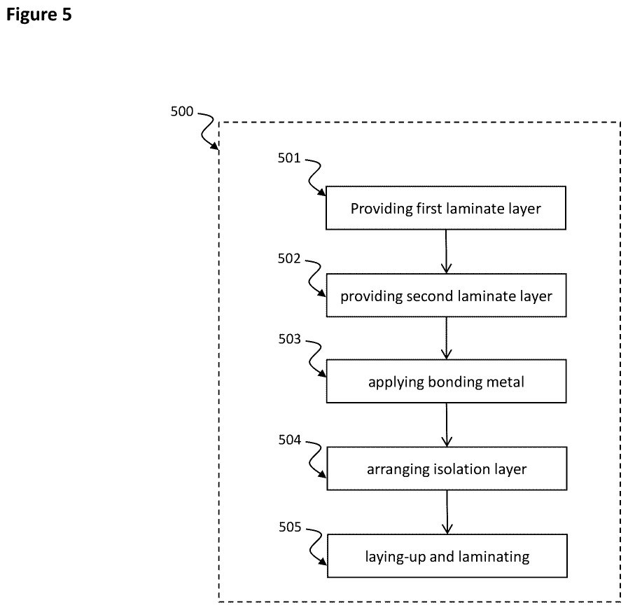

FIG. 5 shows a schematic diagram illustrating a method 500 for producing a semiconductor power entity according to the embodiments.

The semiconductor power entity can be a semiconductor power entity 100, 100b, 100c, 100d, 100e as described above with respect to FIGS. 2a to 2e.

The method 500 includes providing 501 a first laminate layer 110 embedding a first power semiconductor 140, the first laminate layer 110 having a first laminate upper main face 111 and a first laminate lower main face 112 opposing the first laminate upper main face 111, where a first metal layer 113 is arranged at the first laminate upper main face 111 of the first laminate layer 110 and a second metal layer 114 is arranged at the first laminate lower main face 112 of the first laminate layer 110, e.g., as described above with respect to FIGS. 2a to 2e.

The method 500 includes providing 502 a second laminate layer 120 embedding a second power semiconductor 150, the second laminate layer 120 having a second laminate upper main face 121 and a second laminate lower main face 122 opposing the second laminate upper main face 121, where a third metal layer 123 is arranged at the second laminate upper main face 121 of the second laminate layer 120 and a fourth metal layer 124 is arranged at the second laminate lower main face 122 of the second laminate layer 120, e.g., as described above with respect to FIGS. 2a to 2e.

The method 500 includes applying 503 a bonding metal at the second metal layer 114 of the first laminate layer 110 and/or the third metal layer 123 of the second laminate layer 120, the bonding metal being placed between the first power semiconductor 140 and the second power semiconductor 150 and/or between respective electrical contact pairs in the first laminate layer and the second laminate layer, e.g., as described above with respect to FIGS. 2a to 2e.

The method 500 includes arranging 504 an isolation layer 130 between the second metal layer 114 of the first laminate layer 110 and the third metal layer 123 of the second laminate layer 120, e.g., as described above with respect to FIGS. 2a to 2e.

The method 500 includes laying-up and laminating 505 the first laminate layer 110, the second laminate layer 120 and the isolation layer 130 to a semiconductor power entity 100, where the laminating transforms the bonding metal to a connection metal layer 160 forming an electrical connection with the second metal layer 114 and the third metal layer 123, e.g., as described above with respect to FIGS. 2a to 2e or with respect to FIGS. 4a to 4d.

The connection metal layer 160 may be formed simultaneously with the lamination of the first laminate layer 110, the second laminate layer 120 and the isolation layer 130.

The method 500 may further include: applying 503 the bonding metal at the second metal layer 114 of the first laminate layer 110 before the laying-up and laminating 505; and applying the isolation layer 130 at the third metal layer 123 of the second laminate layer 120 before the laying-up and laminating 505, where the isolation layer 130 is structured to form an opening for embedding the bonding metal, e.g., as shown in FIG. 4a.

Applying 503 the bonding metal may include plating, printing or dispending; and applying the isolation layer 130 may include printing, coating, laminating or dispensing, e.g., as shown in FIG. 4a.

The method 500 may further include: applying the isolation layer 130 at the third metal layer 123 of the second laminate layer 120 before the laying-up and laminating 505, where the isolation layer 130 is structured to form an opening for embedding the bonding metal; and placing the bonding metal into the opening of the isolation layer 130 on the third metal layer 123, e.g., as shown in FIG. 4d.

The method 500 may further include: placing the isolation layer 130 between the second metal layer 114 of the first laminate layer 110 and the third metal layer 123 of the second laminate layer 120 during the laying-up and laminating 505, where the isolation layer 130 is non-structured, e.g., as shown in FIG. 4b.

The method 500 may further include: placing the isolation layer 130 between the second metal layer 114 of the first laminate layer 110 and the third metal layer 123 of the second laminate layer 120 during the laying-up and laminating, where the isolation layer 130 is structured to form an opening for embedding the bonding metal, e.g., as shown in FIG. 4c.

Following process steps of the method 500 are optional: drilling holes in the semiconductor power entity 100 extending from the first metal layer 113 to the fourth metal layer 124, where the holes are drilled laterally to the first and second power semiconductors 140, 150; metal plating the holes to form metal plated through holes electrically connecting the first metal layer 113 with the fourth metal layer 124; and structuring the first metal layer 113 and the fourth metal layer 124.

While a particular feature or aspect of the embodiments may have been described with respect to only one of several implementations, such feature or aspect may be combined with one or more other features or aspects of the other implementations as may be desired and advantageous for any given or particular application. Furthermore, to the extent that the terms “include”, “have”, “with”, or other variants thereof are used, such terms are intended to be inclusive in a manner similar to the term “comprise”. Also, the terms “exemplary”, “for example” and “e.g.” are merely meant as an example, rather than the best or optimal. The terms “coupled” and “connected”, along with derivatives may have been used. It should be understood that these terms may have been used to indicate that two elements cooperate or interact with each other regardless whether they are in direct physical or electrical contact, or they are not in direct contact with each other.

Although specific aspects have been illustrated and described herein, it will be appreciated by those of ordinary skill in the art that a variety of alternate and/or equivalent implementations may be substituted for the specific aspects shown and described without departing from the scope of the embodiments. The embodiments are intended to cover any adaptations or variations of the specific aspects discussed herein.

Although the elements in the embodiments may be recited in a particular sequence with corresponding labeling, unless the recitations otherwise imply a particular sequence for implementing some or all of those elements, those elements are not necessarily intended to be limited to being implemented in that particular sequence.

Many alternatives, modifications, and variations will be apparent to those skilled in the art in light of the above teachings. Of course, those skilled in the art readily recognize that there are numerous applications of the embodiments beyond those described herein. While described with reference to one or more particular embodiments, those skilled in the art recognize that many changes may be made thereto without departing from the scope of the embodiments. It is therefore to be understood that within the scope of the embodiments and their equivalents, the embodiments may be practiced otherwise than as specifically described herein.

1. A semiconductor power entity comprising:
a first laminate layer having a first laminate upper main face and a first laminate lower main face opposing the first laminate upper main face;
a second laminate layer having a second laminate upper main face and a second laminate lower main face opposing the second laminate upper main face;
an isolation layer arranged between the first laminate layer and the second laminate layer;
a first metal layer arranged at the first laminate upper main face of the first laminate layer;
a second metal layer arranged at the first laminate lower main face of the first laminate layer;
a third metal layer arranged at the second laminate upper main face of the second laminate layer;
a fourth metal layer arranged at the second laminate lower main face of the second laminate layer; and
a connection metal layer embedded in the isolation layer between the first laminate layer and the second laminate layer, the connection metal layer forming an electrical connection with the second metal layer and the third metal layer.

2. The semiconductor power entity of claim 1, wherein the connection metal layer forms a non-remelting electrical and mechanical connection.

3. The semiconductor power entity of claim 1, wherein the connection metal layer forms one of a diffusion soldering connection or a sintering connection.

4. The semiconductor power entity of claim 1, wherein the first laminate layer is embedding a first power semiconductor and
the second laminate layer is embedding a second power semiconductor.

5. The semiconductor power entity of claim 4, wherein the connection metal layer vertically connects the second metal layer with the third metal layer providing a vertical electrical connection for the first power semiconductor and the second power semiconductor.

6. The semiconductor power entity of claim 4, wherein the connection metal layer forms a direct electrical connection path between the first power semiconductor and the second power semiconductor without a detour via through-hole vias arranged laterally to the two power semiconductors.

7. The semiconductor power entity of claim 1, wherein the second metal layer and/or the third metal layer comprise at least one of copper, gold, silver, palladium or nickel or a combination thereof;
wherein in case of a diffusion soldering connection, the connection metal layer comprises any of the metals tin and indium in combination with any of the metals of the second metal layer or the third metal layer or an alloy thereof;
wherein in case of a sintering connection, the connection metal layer comprises a porous layer of silver or copper with optional polymer filling.

8. The semiconductor power entity of claim 4, wherein the first power semiconductor and the second power semiconductor are configured to form a half bridge configuration.

9. The semiconductor power entity of claim 4,
wherein the first power semiconductor is a vertical device comprising at least one first terminal opposing the first laminate upper main face and a second terminal opposing the first laminate lower main face; and
wherein the second power semiconductor is a vertical device comprising at least one first terminal opposing the second laminate upper main face and a second terminal opposing the second laminate lower main face.

10. The semiconductor power entity of claim 9, comprising:
at least one first via forming an electrical connection between the at least one first terminal of the first power semiconductor and the first metal layer;
at least one second via extending through the first laminate layer and ( ) forming an electrical connection between the second terminal of the first power semiconductor and the second metal layer;
at least one third via forming an electrical connection between the at least one first terminal of the second power semiconductor and the third metal layer; and
at least one fourth via extending through the second laminate layer and forming an electrical connection between the second terminal of the second power semiconductor and the fourth metal layer.

11. The semiconductor power entity of claim 9,
wherein the first power semiconductor has a first semiconductor upper main face and a first semiconductor lower main face opposing the first semiconductor upper main face;
wherein the first semiconductor upper main face is coplanar arranged with the first laminate upper main face to form an electrical connection between the at least one first terminal of the first power semiconductor and the first metal layer at the first laminate upper main face; and
wherein the second terminal of the first power semiconductor forms an electrical connection with the second metal layer at the first laminate lower main face by one or more microvias extending through the first laminate layer.

12. The semiconductor power entity of claim 9,
wherein the second power semiconductor has a second semiconductor upper main face and a second semiconductor lower main face opposing the second semiconductor upper main face;
wherein the second semiconductor upper main face is coplanar arranged with the second laminate upper main face to form an electrical connection between the at least one first terminal of the second power semiconductor and the third metal layer at the second laminate upper main face; and
wherein the second terminal of the second power semiconductor forms an electrical connection with the fourth metal layer at the second laminate lower main face by one or more microvias extending through the second laminate layer.

13. A method for producing a semiconductor power entity, the method comprising:
providing a first laminate layer embedding a first power semiconductor, the first laminate layer having a first laminate upper main face and a first laminate lower main face opposing the first laminate upper main face, wherein a first metal layer is arranged at the first laminate upper main face of the first laminate layer and a second metal layer is arranged at the first laminate lower main face of the first laminate layer;
providing a second laminate layer embedding a second power semiconductor, the second laminate layer having a second laminate upper main face and a second laminate lower main face opposing the second laminate upper main face, wherein a third metal layer is arranged at the second laminate upper main face of the second laminate layer and a fourth metal layer is arranged at the second laminate lower main face of the second laminate layer;
applying a bonding metal at the second metal layer of the first laminate layer and/or the third metal layer of the second laminate layer, the bonding metal being placed between the first power semiconductor and the second power semiconductor and/or between respective electrical contact pairs in the first laminate layer and the second laminate layer,
arranging an isolation layer between the second metal layer of the first laminate layer and the third metal layer of the second laminate layer; and
laying-up and laminating the first laminate layer, the second laminate layer, and the isolation layer to a semiconductor power entity, wherein the laminating transforms the bonding metal to a connection metal layer forming an electrical connection with the second metal layer and the third metal layer.

14. The method of claim 13, comprising:
applying the bonding metal at the second metal layer of the first laminate layer; before the laying-up and laminating; and
applying the isolation layer at the third metal layer of the second laminate layer before the laying-up and laminating, wherein the isolation layer is structured to form an opening for embedding the bonding metal.

15. The method of claim 14, wherein applying the bonding metal comprises plating, printing or dispending; and wherein applying the isolation layer comprises printing, coating, laminating or dispensing.

16. The method of claim 13, further comprising:
applying the isolation layer at the third metal layer of the second laminate layer before the laying-up and laminating, wherein the isolation layer is structured to form an opening for embedding the bonding metal; and
placing the bonding metal into the opening of the isolation layer on the third metal layer.

17. The method of claim 13, comprising:
placing the isolation layer between the second metal layer of the first laminate layer and the third metal layer of the second laminate layer during the laying-up and laminating, wherein the isolation layer is non-structured.

18. The method of claim 13, comprising:
placing the isolation layer between the second metal layer of the first laminate layer and the third metal layer of the second laminate layer during the laying-up and laminating, wherein the isolation layer is structured to form an opening for embedding the bonding metal.

19. The semiconductor power entity of claim 9, wherein the first semiconductor lower main face is coplanar arranged with the first laminate lower main face to form an electrical connection between the second terminal of the first power semiconductor and the second metal layer at the first laminate lower main face; and the at least one first terminal of the first power semiconductor forms an electrical connection with the first metal layer at the first laminate upper main face by one or more microvias extending through the first laminate layer.

20. The semiconductor power entity of claim 9,
wherein the second power semiconductor has a second semiconductor upper main face and a second semiconductor lower main face opposing the second semiconductor upper main face;
wherein the second semiconductor lower main face is coplanar arranged with the second laminate lower main face to form an electrical connection between the second terminal of the second power semiconductor and the fourth metal layer at the second laminate lower main face; and
wherein the at least one first terminal of the second power semiconductor forms an electrical connection with the third metal layer at the second laminate upper main face by one or more microvias extending through the second laminate layer.
